(19) United States
(12) Patent Application Publication
(10) Pub. No.: US 2026/0282560 A1
(43) Pub. Date: Sep. 17, 2026

(54) SEMICONDUCTOR DEVICE AND CAN PROTECTION CIRCUIT INCLUDING SAME

(71) Applicant: SK keyfoundry Inc., Cheongju-si (KR)

(72) Inventors: Hee Hwan JI, Daejeon (KR); Gyeong Sun PARK, Seoul (KR)

(73) Assignee: SK keyfoundry Inc., Cheongju-si (KR)

(21) Appl. No.: 19/235,941

(22) Filed: Jun. 12, 2025

(30) Foreign Application Priority Data
Mar. 12, 2025 (KR) 10-2025-0032288

(51) Int. Cl. H10D 89/60

(52) U.S. Cl. CPC H10D 89/713

(57) ABSTRACT

A semiconductor device and a controller area network (CAN) protection circuit including the semiconductor device are provided. The semiconductor device includes a first bidirectional silicon controlled rectifier (SCR) device, a second bidirectional SCR device, and a third bidirectional SCR device, all formed on a single semiconductor chip. Each SCR device includes a semiconductor substrate of a first conductivity type, a device isolation layer disposed on the substrate, a first well region of a second conductivity type, and second and third well regions of the first conductivity type spaced apart beneath the device isolation layer. Two doped regions are formed in the second and third well regions. No guard ring is disposed between the SCR devices. A CAN high terminal of the first SCR device is electrically connected to a CAN high terminal of the second SCR device, and a CAN low terminal of the second SCR device is electrically connected to a CAN low terminal of the third SCR device.

### CROSS-REFERENCE TO RELATED APPLICATION

This application claims the benefit under 35 U.S.C. § 119(a) of Korean Patent Application No. 10-2025-0032288, filed on Mar. 12, 2025, the entire disclosure of which is incorporated herein by reference for all purposes.

### BACKGROUND

### 1. Field

The following description relates to a semiconductor device for Electro-Static Discharge (ESD) protection and a Controller Area Network (CAN) protection circuit including the same.

### 2. Discussion of Related Art

The statements in this section merely provide background information related to the present disclosure and do not necessarily constitute prior art.

Silicon Controlled Rectifier (SCR) devices are semiconductor components commonly employed as electrostatic discharge (ESD) protection elements in high-voltage applications. The devices are employed to protect integrated circuits (ICs) from electrical overstress (EOS) conditions that may result from ESD events. When an ESD event induces an electrical overstress (EOS), unprotected Integrated Circuits (ICs) within electronic devices and systems may suffer permanent damage. Any damage to an IC within an electronic device or system may lead to malfunction or failure of the electronic product.

A Controller Area Network (CAN) transceiver protection circuit typically includes one or more SCR devices configured to discharge externally applied electrostatic discharge (ESD) to ground, thereby protecting internal circuit components. In addition to providing ESD protection, there is a need to reduce the overall size of CAN transceiver protection circuits, in order to facilitate miniaturization of the circuit assembly.

There is a growing demand for SCR devices that meet electrostatic discharge (ESD) protection requirements that exceed the Human Body Model (HBM) standard, extending to more stringent system-level ESD specifications. While a discharge current of approximately 1.33 A in a Transmission Line Pulse (TLP) test may be sufficient to satisfy a typical 2 kV HBM requirement, system-level ESD testing may demand discharge currents of 30 A or higher. Accordingly, there is a need for highly efficient SCR devices capable of conducting such high current levels without device failure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes a first bidirectional silicon controlled rectifier (SCR) device, a second bidirectional SCR device, and a third bidirectional SCR device. Each of the first, second, and third bidirectional SCR devices includes: a semiconductor substrate of a first conductivity type; a device isolation layer disposed on the semiconductor substrate; a first well region of a second conductivity type, a second well region of the first conductivity type, and a third well region of the first conductivity type, each of the first to third well regions being formed separately from one another beneath the device isolation layer; and two doped regions respectively formed in the second and third well regions. The first, second, and third bidirectional SCR devices are integrated on a single chip.

The two doped regions may include a doped region of the first conductivity type and a doped region of the second conductivity type, and the doped region of the first conductivity type may be smaller in size than the doped region of the second conductivity type.

A doped region of the first bidirectional SCR device may be electrically connected to a ground (GND) terminal and a CAN high terminal, a doped region of the second bidirectional SCR device may be electrically connected to the CAN high terminal and a CAN low terminal, a doped region of the third bidirectional SCR device may be electrically connected to the CAN low terminal and the ground (GND) terminal, the CAN high terminal of the first bidirectional SCR device may be electrically connected to the CAN high terminal of the second bidirectional SCR device, and the CAN low terminal of the second bidirectional SCR device may be electrically connected to the CAN low terminal of the third bidirectional SCR device.

No doped region may be formed in the first well region.

One or two deep trench isolation (DTI) structures may be formed between the first and second bidirectional SCR devices and between the second and third bidirectional SCR devices.

No deep trench isolation (DTI) structure may be formed between the first an second bidirectional SCR devices and between the second and third bidirectional SCR devices.

The semiconductor substrate of the first conductivity type may include: a buried layer of the second conductivity type; an epitaxial layer of the first conductivity type formed over the buried layer; and a deep well region of the second conductivity type formed beneath the first well region. The deep well region may electrically connect the first well region to the buried layer.

In another general aspect, a semiconductor device includes a first bidirectional silicon controlled rectifier (SCR) device, a second bidirectional SCR device, and a third bidirectional SCR device, each disposed on a single chip. Each of the first, second, and third bidirectional SCR devices includes: a first well region of a second conductivity type formed at a central portion; a second well region and a third well region of a first conductivity type symmetrically formed on opposite sides of the first well region; a deep well region of the second conductivity type formed beneath the first well region; and a doped region of the first conductivity type and a doped region of the second conductivity type formed in the second well region and the third well region.

The first bidirectional SCR device may be electrically connected between a ground (GND) terminal and a CAN high terminal; the second bidirectional SCR device may be electrically connected between the CAN high terminal and a CAN low terminal; the third bidirectional SCR device may be electrically connected between the CAN low terminal and the ground terminal; the CAN high terminal of the first bidirectional SCR device may be metal-connected to the CAN high terminal of the second bidirectional SCR device; and the CAN low terminal of the second bidirectional SCR device is metal-connected to the CAN low terminal of the third bidirectional SCR device.

The semiconductor device may further includes: a guard ring region of the second conductivity type formed to surround the first, second, and third bidirectional SCR devices; and a deep trench isolation (DTI) structure formed outside the guard ring region.

In another general aspect, a controller area network (CAN) protection circuit includes: a first bidirectional SCR device, a second bidirectional SCR device, and a third bidirectional SCR device; and a CAN receiver having a VCC terminal, a CAN high terminal, a CAN low terminal, and a ground (GND) terminal. The first bidirectional SCR device is connected between the CAN high terminal and the GND terminal. The second bidirectional SCR device is connected between the CAN high terminal and the CAN low terminal; and the third bidirectional SCR device is connected between the CAN low terminal and the GND terminal.

The first, second, and third bidirectional SCR devices may be implemented on a single chip.

The CAN protection circuit may further include a semiconductor protection device connected between the VCC terminal and the GND terminal. The semiconductor protection device may include one of a bidirectional SCR device, a bipolar junction transistor (BJT), or a gate-grounded NMOS (GGNMOS) device.

Each of the first, second, and third bidirectional SCR devices may include: a semiconductor substrate of a first conductivity type; a device isolation layer formed on the semiconductor substrate; a first well region of a second conductivity type, a second well region of the first conductivity type, and a third well region of the first conductivity type, each formed separately beneath the device isolation layer; and doped regions of the first conductivity type and the second conductivity type respectively formed in the second well region and the third well region. No doped region may be formed in the first well region.

In another general aspect, a semiconductor device includes: a first bidirectional silicon controlled rectifier (SCR) device, a second bidirectional SCR device, and a third bidirectional SCR device, each disposed on a single chip; a first well region of a second conductivity type formed at a central portion of the chip; a second well region and a third well region of a first conductivity type symmetrically formed on respective left and right sides of the first well region; a doped region of the first conductivity type formed in each of the second and third well regions; and doped regions of the second conductivity type formed on opposite sides of the doped region of the first conductivity type in each of the second and third well regions. A controller area network (CAN) high terminal is connected to the doped region of the first conductivity type and the doped regions of the second conductivity type in the second well region, and a CAN low terminal is connected to the doped region of the first conductivity type and the doped regions of the second conductivity type formed in the third well region.

A deep trench isolation (DTI) structure may be formed to surround the first, second, and third bidirectional SCR devices, and a guard ring of the second conductivity type may be formed outside the DTI structure.

The first bidirectional SCR device may be connected between a ground (GND) terminal and the CAN high terminal, the second bidirectional SCR device may be connected between the CAN high terminal and the CAN low terminal, and the third bidirectional SCR device may be connected between the CAN low terminal and the GND terminal.

The GND terminal of the first bidirectional SCR device may include a fourth well region of the first conductivity type, the fourth well region including doped regions of both the first and second conductivity types. The ground terminal of the third bidirectional SCR device may include a fifth well region of the first conductivity type, the fifth well region including doped regions of both the first and second conductivity types.

Other features and aspects will be apparent from the following detailed description, the drawings, and the claims.

### BRIEF DESCRIPTION OF THE DRAWINGS

FIG. 1 illustrates a circuit diagram of a CAN transceiver protection circuit according to the related art for comparison with the present disclosure.

FIG. 2 illustrates a layout diagram showing the configuration of a CAN transceiver protection circuit according to the related art, related to the drive of a vehicle LED lamp.

FIG. 3 illustrates a cross-sectional view of an ESD protection semiconductor device according to the related art.

FIG. 4 illustrates a cross-sectional view of an ESD protection semiconductor device according to a first example of the present disclosure.

FIG. 5 illustrates a plan view of an ESD protection semiconductor device according to the first example of the present disclosure.

FIG. 6 illustrates a cross-sectional view of an ESD protection semiconductor device according to a second example of the present disclosure.

FIG. 7 illustrates a plan view of an ESD protection semiconductor device according to the second example of the present disclosure.

FIG. 8 illustrates a cross-sectional view of an ESD protection semiconductor device according to a third example of the present disclosure.

FIG. 9 illustrates a plan view of an ESD protection semiconductor device according to the third example of the present disclosure.

FIG. 10 illustrates a cross-sectional view of an ESD protection semiconductor device according to a fourth example of the present disclosure.

FIG. 11 illustrates a plan view of an ESD protection semiconductor device according to the fourth example of the present disclosure.

FIG. 12 illustrates a circuit diagram illustrating a CAN transceiver protection circuit applicable to the present disclosure.

FIG. 13 an operational state of a CAN transceiver protection circuit according to an example of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

In one general aspect, the present disclosure is suggested to improve the structure of the SCR device to enable integration within a CAN transceiver protection circuit, thereby allowing the circuit to be designed in a more compact form.

In another general aspect, the present disclosure is suggested to provide a semiconductor device that is integrated on-chip within an IC, and is capable of withstanding ESD events at the system level, which are more severe than those defined by the Human Body Model (HBM).

In another general aspect, the present disclosure is suggested to develop a high-efficiency SCR device that is sufficiently small to be implemented on-chip within an IC and capable of conducting high discharge currents.

The technical problems addressed by the present disclosure are not limited to those mentioned above, and other technical challenges not explicitly described will be readily understood by those skilled in the art based on the following detailed description.

A detailed description is given below, with reference to attached drawings.

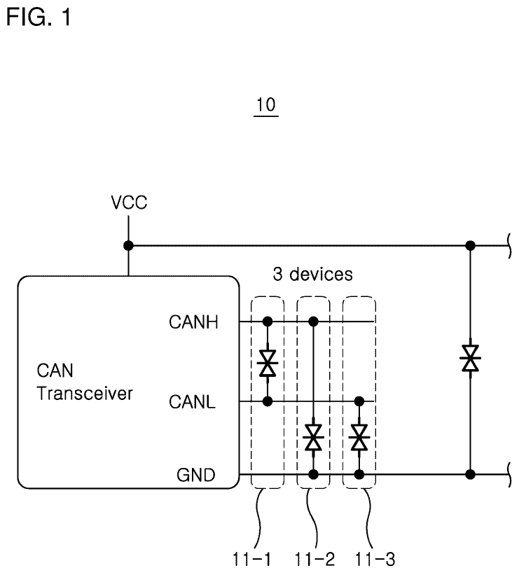

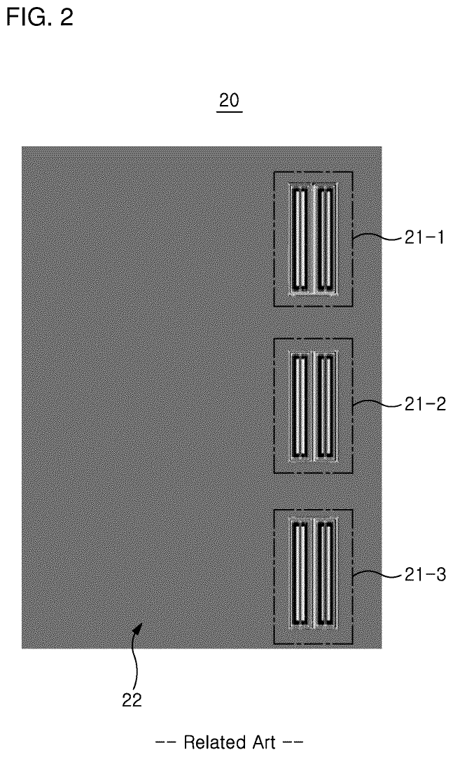

FIGS. 1 and 2 illustrate circuit diagrams of conventional CAN transceiver protection circuits.

Referring to FIG. 1, the CAN transceiver protection circuit 10 includes four pin terminals: a VCC terminal, a CAN high terminal CANH, a CAN low terminal CANL, and a ground terminal GND. The circuit is provided with three bidirectional SCR devices, namely a first bidirectional SCR device 11-1, a second bidirectional SCR device 11-2, and a third bidirectional SCR device 11-3. The CAN transceiver protection circuit 10 is configured such that, when a sudden surge voltage is applied, the first to third bidirectional SCR devices 11-1, 11-2, 11-3 discharge the surge voltage to the ground, thereby preventing damage or failure of other components.

In FIG. 1, the first to third bidirectional SCR devices 11-1, 11-2, 11-3 are individually configured, and a detailed layout configuration can be referenced in FIG. 2.

Referring to FIG. 2, the CAN transceiver protection circuit 20 also comprises bidirectional SCR devices 21-1, 21-2, 21-3 and components 22 for driving vehicle LEDs. When a surge voltage is applied externally, the circuit is designed to discharge the surge voltage to the ground.

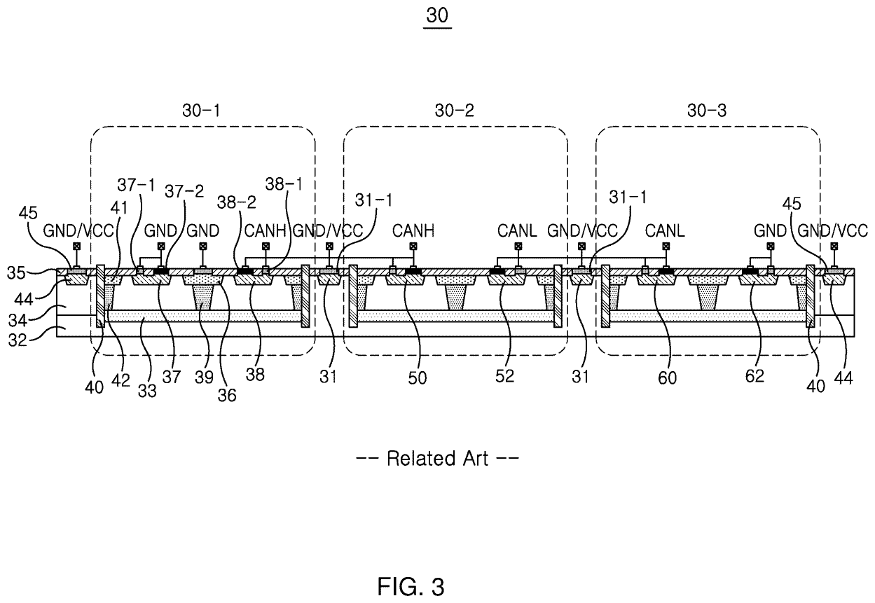

Since the first to third bidirectional SCR devices 21-1, 21-2, 21-3 are individually configured, the layout size is inevitably designed to be larger. The detailed structure can be referenced in FIG. 3.

FIG. 3 illustrates a cross-sectional view of an ESD protection semiconductor device according to the related art.

Referring to FIG. 3, a semiconductor device 30 includes first to third bidirectional SCR devices 30-1, 30-2, 30-3, and the first to third bidirectional SCR devices 30-1, 30-2, 30-3 may be configured in a structure in which they are separated from one another by a guard ring 31.

Since the first to third bidirectional SCR devices 30-1, 30-2, 30-3 have the same structure, only one will be described in detail. However, the doped regions formed in each of the bidirectional SCR devices 30-1, 30-2, 30-3 are connected to different terminals, and this will be explained separately.

As shown in FIG. 3, the first bidirectional SCR device 30-1 includes a P-type substrate 32.

An N-type buried layer (NBL) 33, doped with a high concentration of N-type impurities, and a P-type epitaxial layer 34 are formed in the P-type substrate 32. The P-type epitaxial layer 34 may be formed by an epitaxial growth process. Additionally, a P-type buried layer (PBL, not shown) may optionally be formed in the P-type epitaxial layer 34.

A device isolation layer 35 is formed on the P-type epitaxial layer 34. The device isolation layer 35 may have a Shallow Trench Isolation (STI) structure or a Local Oxidation of Silicon (LOCOS) structure, and may be formed of an oxide film.

The P-type epitaxial layer 34 includes a first well region 36, a second well region 37, and a third well region 38. These well regions may be formed deeper than the bottom of the device isolation layer 35. The first well region 36 may be N-type, and the second and third well regions 37 and 38 may be P-type. The first well region 36 may be referred to as NW, the second well region 37 as first PW, and the third well region 38 as second PW. The second well region 37 and the third well region 38 may be formed on either side of the first well region 36, spaced apart therefrom. The first well region 36 and the second well region 37 are spaced apart from each other by a predetermined distance, and the first well region 36 and the third well region 38 are similarly spaced apart by a predetermined distance. The first to third well regions 36, 37, 38 may be formed to have substantially the same size.

The P-type epitaxial layer 34 may further include an N-type deep well (DNW) region 39 that connects the first well region 36 to the N-type buried layer 33. The N-type deep well region 39 may be formed beneath the first well region 36 within the P-type epitaxial layer 34, and is configured to be in contact with the N-type buried layer 33.

The second well region 37 and the third well region 38 may include doped regions, whereas no doped region is formed in the first well region 36.

A P+ region 37-1 and an N+ region 37-2 are formed in the second well region 37. The P+ region 37-1 and the N+ region 37-2 of the second well region 37 are connected to a ground (GND) terminal. In the second well region 37, the P+ region 37-1 is formed smaller in size than the N+ region 37-2. Forming the P+ region 37-1 smaller allows current to flow more effectively and enhances the operating characteristics of the SCR device.

A P+ region 38-1 and an N+ region 38-2 are formed in the third well region 38. The structure is symmetric to that of the second well region 37. Similar to the second well region 37, the P+ region 38-1 of the third well region 38 is formed smaller in size than the N+ region 38-2. The P+ region 38-1 and the N+ region 38-2 of the third well region 38 are connected to a CAN High terminal.

As shown in FIG. 3, the second bidirectional SCR device 30-2 has the same structure as the first bidirectional SCR device 30-1. However, the P+ and N+ regions of the second well region 50 of the second bidirectional SCR device 30-2 are connected to the CAN High terminal, and are therefore electrically connected to the P+ region 38-1 and the N+ region 38-2 of the third well region 38 of the first bidirectional SCR device 30-1. In addition, the P+ and N+ regions of a third well region 52 of the second bidirectional SCR device 30-2 are connected to a CAN Low terminal.

As shown in FIG. 3, the third bidirectional SCR device 30-3 has the same structure as the first second bidirectional SCR device 30-1 or the second bidirectional SCR device 30-2. However, the P+ and N+ regions of the second well region 60 of the third bidirectional SCR device 30-3 are connected to a CAN Low terminal, and are therefore electrically connected to the P+ and N+ regions of the third well region 52 of the second bidirectional SCR device 30-2. In addition, the P+ and N+ regions of the third well region 62 of the third bidirectional SCR device 30-3 are connected to a ground (GND) terminal.

As further shown in FIG. 3, the ESD protection semiconductor device 30 includes a deep trench isolation (DTI) 40 that extends from the upper surface of the substrate 32 down to the N-type buried layer 33 to provide device isolation. Along the sidewall of the DTI 40, an NW region 41 is formed, and an N-type deep well region (DNW) 42 is formed between the NW region 41 and the N-type buried layer 33. Further, between and outwardly from the DTI 40, a fourth well region 44 is formed, and a heavily doped region 45 is formed on the fourth well region 44. The heavily doped region 45 is connected to either the GND terminal or the VCC terminal. The fourth well region 44 may be of either N-type or P-type. When the fourth well region 44 is N-type, the heavily doped region 45 is also N-type and connected to the VCC terminal. Conversely, when the fourth well region 44 is P-type, the heavily doped region 45 is also P-type and connected to the GND terminal. In the case where both the fourth well region 44 and the heavily doped region 45 are of N-type, it is possible to more effectively suppress a reduction in discharge current due to parasitic PNP operation during application of a negative ESD pulse, as compared to when both are of P-type.

Referring again to FIG. 3, the first to third bidirectional SCR devices 30-1, 30-2, 30-3 are separated from one another by guard rings 31, 31-1 formed along the sidewalls of the DTI 40, and are disposed with predetermined spacing therebetween to form the semiconductor device 30. That is, the first to third bidirectional SCR devices 30-1, 30-2, 30-3 are configured independently of one another. In the conventional structure, guard rings 31, 31-1 are formed to isolate each of the bidirectional SCR devices 30-1, 30-2, 30-3. However, the space required for forming such guard rings imposes a limitation on reducing the overall size of the circuit.

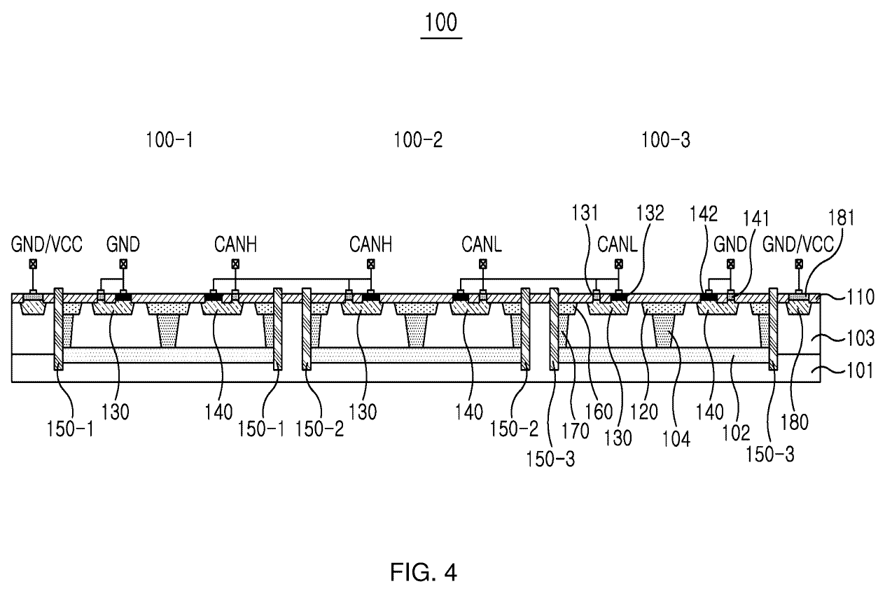

FIG. 4 illustrates a cross-sectional view of an ESD protection semiconductor device according to a first example of the present disclosure. Since the semiconductor device of the present disclosure, as described below, has a structure similar to the semiconductor device described with reference to FIG. 3, a description of components having the same structure may be omitted.

An ESD protection semiconductor device 100 of FIG. 4 differs from that of FIG. 3 in that no guard ring is formed between the DTIs that partition the respective devices. Other components remain identical. In addition, the first to third bidirectional SCR devices 100-1, 100-2, 100-3 are integrated into a single chip.

As shown in FIG. 4, the ESD protection semiconductor device 100 includes the first to third bidirectional SCR devices 100-1, 100-2, 100-3 integrated into one chip. Any one of the bidirectional SCR devices may include: a P-type substrate 101; a P-type epitaxial layer 103; an N-type buried layer 102; a device isolation layer 110; a first well region 120; a second well region 130; a third well region 140; an N-type deep well region 104; and P+ regions 131, 141 and N+ regions 132, 142, which are formed in the second well region 130 and the third well region 140. An NW region 160 is formed along a sidewall of a DTI 150-3, and an N-type deep well (DNW) region 170 is formed between the NW region 160 and the N-type buried layer 102. Further, outside the DTI 150, a fourth well region 180 and a heavily doped region 181 formed over the fourth well region 180 are provided. The heavily doped region 181 is connected to either a GND terminal or a VCC terminal. The fourth well region 180 may be of either N-type or P-type. When the fourth well region 180 is N-type, the heavily doped region 181 is also N-type and is connected to the VCC terminal. Conversely, when the fourth well region 180 is P-type, the heavily doped region 181 is also P-type and is connected to the GND terminal. When the fourth well region 180 and the heavily doped region 181 are N-type, it can more effectively prevent the phenomenon of discharge current reduction caused by parasitic PNP operation under a negative ESD pulse, compared to when the fourth well region 180 and the heavily doped region 181 are P-type.

Referring to FIG. 4, the third well region 140 of the first bidirectional SCR device 100-1 and the second well region 130 of the second bidirectional SCR device 100-2 are connected to a CAN High terminal, and the third well region 140 of the second bidirectional SCR device 100-2 and the second well region 130 of the third bidirectional SCR device 100-3 are connected to a CAN Low terminal. In this way, due to the fact that metal interconnections are provided respectively between the first bidirectional SCR device 100-1 and the second bidirectional SCR device 100-2, and between the second bidirectional SCR device 100-2 and the third bidirectional SCR device 100-3, it is not necessary, as in the related art, to provide a guard ring between the DTIs for device isolation.

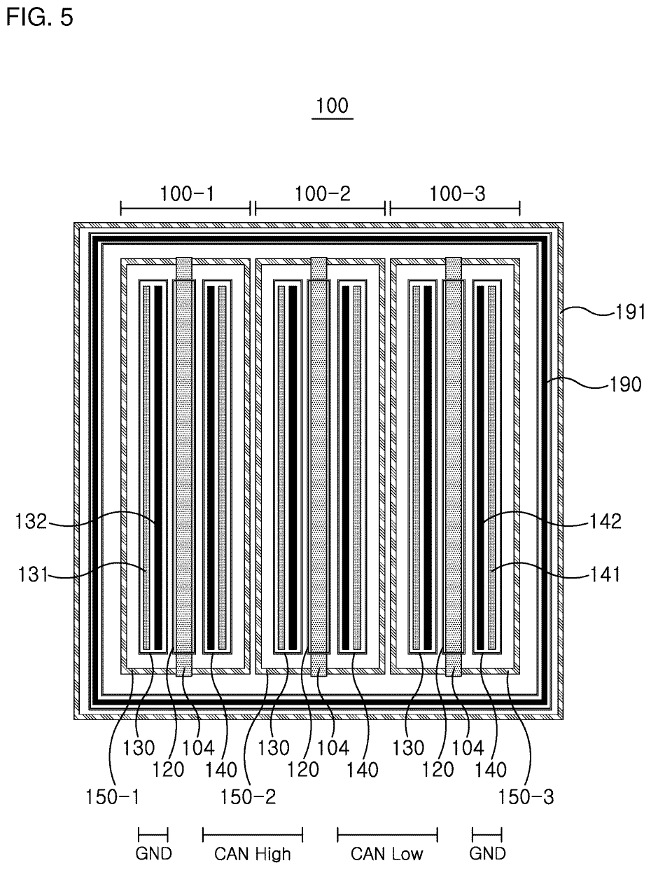

FIG. 5 illustrates a plan view of an ESD protection semiconductor device according to the first example of the present disclosure.

Referring to FIG. 5, the ESD protection semiconductor device 100 includes the first to third bidirectional SCR devices 100-1, 100-2, 100-3. Each of the bidirectional SCR devices 100-1, 100-2, 100-3 is surrounded by first to third DTIs 150-1, 150-2, 150-3, respectively. Accordingly, the first to third bidirectional SCR devices 100-1, 100-2, 100-3 may be arranged spaced apart from each other by a distance corresponding to the spacing between the DTIs.

From a plan view perspective, the first to third bidirectional SCR devices 100-1, 100-2, 100-3 may respectively include the first to third well regions 120, 130, 140. The N-type deep well region 104 may be formed below the first well region 120. On both sides of the first well region 120, the second well region 130 and the third well region 140 are formed. In the second well region 130 and the third well region 140, P+ regions 131, 141 and N+ regions 132, 142 are formed.

In FIG. 5, the ESD protection semiconductor device 100 may include a CAN High terminal region, a CAN Low terminal region, and a GND terminal region. The CAN High terminal of the first bidirectional SCR device 100-1 and the CAN High terminal of the second bidirectional SCR device 100-2 are connected via metal. The CAN Low terminal of the second bidirectional SCR device 100-2 and the CAN Low terminal of the third bidirectional SCR device 100-3 are also connected via metal. The first to third bidirectional SCR devices 100-1, 100-2, 100-3 are all electrically connected in structure.

In FIG. 5, an N-type guard ring region 190 may be formed in a ring shape along the outermost perimeter, surrounding the first to third bidirectional SCR devices 100-1, 100-2, 100-3. As illustrated, an outermost DTI 191 may be further formed outward of the N-type guard ring region 190. The outermost DTI 191 serves to provide isolation from other devices.

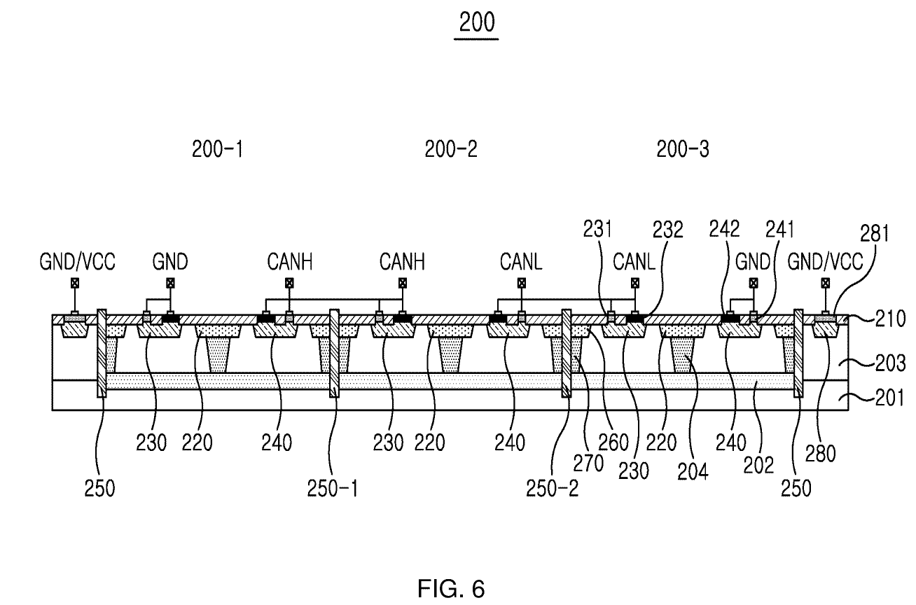

FIG. 6 illustrates a cross-sectional view of an ESD protection semiconductor device according to a second example of the present disclosure.

Referring to FIG. 6, an ESD protection semiconductor device 200 differs from that shown in FIG. 4 in that only one DTI 250-1, 250-2 is formed between the first bidirectional SCR device 200-1 and the second bidirectional SCR device 200-2, and between the second bidirectional SCR device 200-2 and the third bidirectional SCR device 200-3, respectively. The first to third bidirectional SCR devices 200-1, 200-2, 200-3 are configured in a one-chip structure.

Referring to FIG. 6, the ESD protection semiconductor device 200 includes first to third bidirectional SCR devices 200-1, 200-2, 200-3. Any one of the bidirectional SCR devices may include a P-type substrate 201, a P-type epitaxial layer 203, an N-type buried layer 202, a device isolation layer 210, a first well region 220, a second well region 230, a third well region 240, an N-type deep well region 204, and P+ regions 231, 241 and N+ regions 232, 242 doped in the second well region 230 and the third well region 240. An NW 260 is formed along the sidewall of DTI 250, 250-1, and an N-type deep well region (DNW) 270 is formed between NW 260 and the N-type buried layer 202. In an outward direction from DTI 250, a fourth well region 280 and a heavily doped region 281 over the fourth well region 280 are formed, where the heavily doped region 281 is connected to a GND terminal or a VCC terminal. The fourth well region 280 may be either N-type or P-type. When the fourth well region 280 is N-type, the heavily doped region 281 is also N-type and is connected to the VCC terminal. Conversely, when the fourth well region 280 is P-type, the heavily doped region 281 is also P-type and is connected to the GND terminal. When the fourth well region 280 and the heavily doped region 281 are of N type, it is possible to more effectively prevent the phenomenon in which the discharge current is reduced due to a parasitic PNP operation upon application of a negative ESD pulse, as compared to the case where the fourth well region 280 and the heavily doped region 281 are of P type.

In the configuration of the second example shown in FIG. 6, as in the first example, the CAN High terminal of the third well region 240 of the first bidirectional SCR device 200-1 and the CAN High terminal of the second well region 230 of the second bidirectional SCR device 200-2 are connected via metal, and the CAN Low terminal of the third well region 240 of the second bidirectional SCR device 200-2 and the CAN Low terminal of the second well region 230 of the third bidirectional SCR device 200-3 are also connected via metal. Therefore, even if only one DTI is formed between adjacent bidirectional SCR devices, it does not present a problem.

As shown in FIG. 6, when only one DTI 250-1 is formed between the first bidirectional SCR device 200-1 and the second bidirectional SCR device 200-2, and only one DTI 250-2 is formed between the second bidirectional SCR device 200-2 and the third bidirectional SCR device 200-3, the overall size can be further reduced compared to the case of forming two DTIs as in FIG. 4.

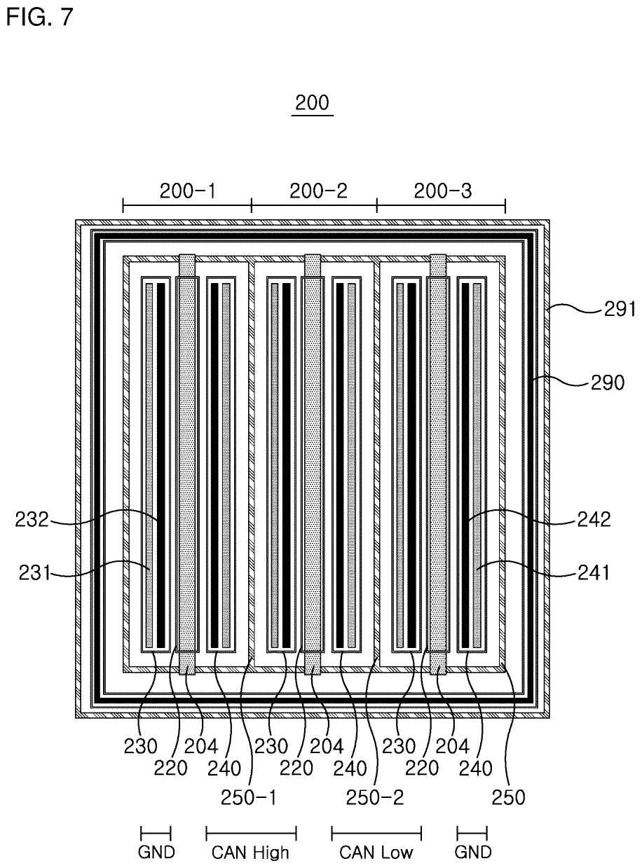

FIG. 7 illustrates a plan view of an ESD protection semiconductor device according to the second example of the present disclosure.

Referring to FIG. 7, the ESD protection semiconductor device 200 includes the first to third bidirectional SCR devices 200-1, 200-2, 200-3, and the first to third bidirectional SCR devices 200-1, 200-2, 200-3 may each be surrounded by a DTI 250. The first to third bidirectional SCR devices 200-1, 200-2, 200-3 are partitioned by DTIs 250-1, 250-2 formed between them. From the plan view perspective, each of the first to third bidirectional SCR devices 200-1, 200-2, 200-3 may include the first to third well region 220, 230, 240, respectively. The N-type deep well region (DNW) 204 may be formed beneath the first well region 220. On both sides of the first well region 220, the second well region 230 and the third well region 240 are formed, and P+ regions 231, 241 and N+ regions 232, 242 are formed in the second well region 230 and the third well region 240.

In FIG. 7, the ESD protection semiconductor device 200 may include a CAN High terminal region, a CAN Low terminal region, and a GND terminal region.

The CAN High terminal of the first bidirectional SCR device 200-1 and the CAN High terminal of the second bidirectional SCR device 200-2 are connected via metal. The CAN Low terminal of the second bidirectional SCR device 200-2 and the CAN Low terminal of the third bidirectional SCR device 200-3 are also connected via metal. The first to third bidirectional SCR devices 200-1, 200-2, 200-3 are all electrically connected in structure.

As shown in FIG. 7, an N-type guard ring region 290 may be formed in a ring shape surrounding the first to third bidirectional SCR devices 200-1, 200-2, 200-3 along the outermost periphery. In addition, as shown in the drawing, an outermost DTI 291 for isolation from other devices may be further formed on the outer side of the N-type guard ring region 290.

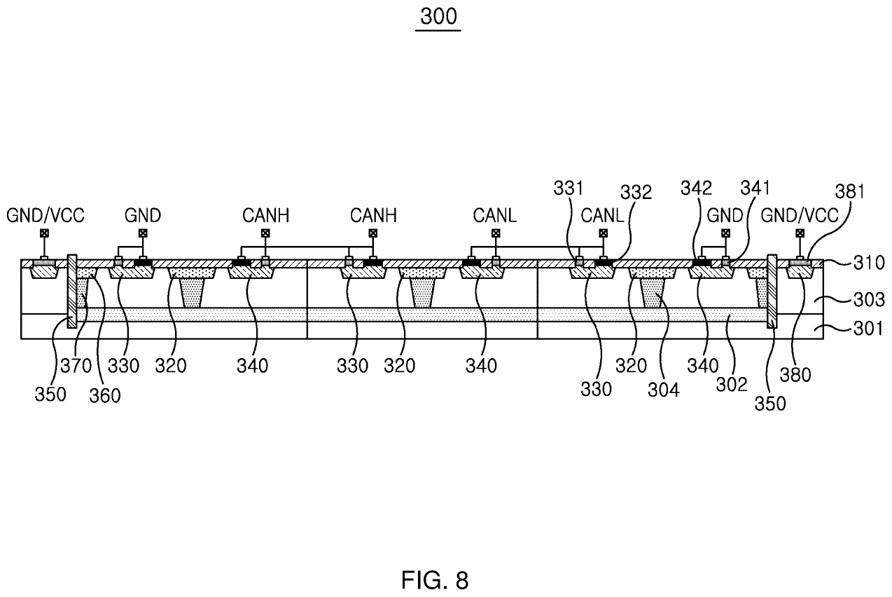

FIG. 8 illustrates a cross-sectional view of an ESD protection semiconductor device according to a third example of the present disclosure.

Compared to the ESD protection semiconductor device 200 in FIG. 6, an ESD protection semiconductor device 300 shown in FIG. 8 differs in that no DTI is formed between a first bidirectional SCR device 300-1 and a second bidirectional SCR device 300-2, nor between the second bidirectional SCR device 300-2 and a third bidirectional SCR device 300-3. That is, the bidirectional SCR devices 300-1, 300-2, 300-3 are formed continuously without any isolation structures such as DTI. These devices are also configured as a single chip.

As shown in FIG. 8, a DTI 350 is still formed along the outer perimeter of the bidirectional SCR devices 300-1, 300-2, 300-3. An NW 360 is formed on the inner side of the DTI 350, and an N-type deep well region (DNW) 370 is formed between the NW 360 and an N-type buried layer 302. In the outward direction of the DTI 350, a fourth well region 380 and a heavily doped region 381 above the fourth well region 380 are formed, respectively. The heavily doped region 381 is connected to either a GND terminal or a VCC terminal. The fourth well region 380 may be either N-type or P-type. When the fourth well region 380 is N-type, the heavily doped region 381 is also N-type and connected to the VCC terminal. Conversely, when the fourth well region 380 is P-type, the heavily doped region 381 is also P-type and connected to the GND terminal. When the fourth well region 380 and the heavily doped region 381 are N-type, this configuration can more effectively prevent a reduction in discharge current due to parasitic PNP operation under a negative ESD pulse, compared to when they are P-type.

All other elements—namely, a P-type substrate 301, a P-type epitaxial layer 303, an N-type buried layer 302, a device isolation layer 310, a first well region 320, a second well region 330, a third well region 340, an N-type deep well region 304, and P+ regions 331, 341 and N+ regions 332, 342 doped in the second well region 330 and third well region 340 are the same as in the previous examples. The CAN High terminal of the third well region 340 of the first bidirectional SCR device 300-1 and the CAN High terminal of the second well region 330 of the second bidirectional SCR device 300-2 are connected via metal. Likewise, the CAN Low terminal of the third well region 340 of the second bidirectional SCR device 300-2 and the CAN Low terminal of the second well region 330 of the third bidirectional SCR device 300-3 are also connected via metal.

As shown in FIG. 8, by configuring the device without forming a DTI between the first bidirectional SCR device 300-1 and second bidirectional SCR device 300-2, and between the second bidirectional SCR device 300-2 and third bidirectional SCR device 300-3, the layout can be made smaller compared to that in FIG. 4 and FIG. 6.

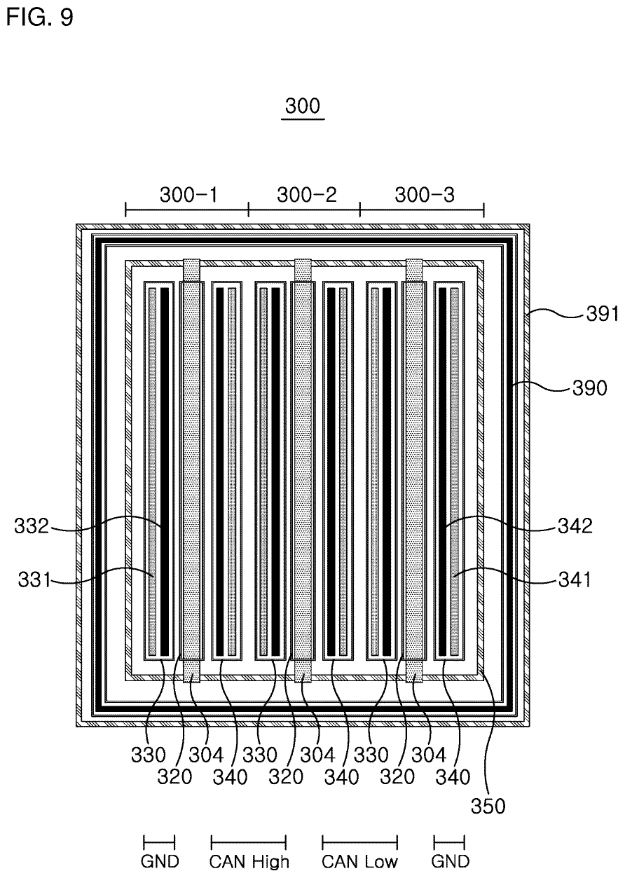

FIG. 9 illustrates a plan view of an ESD protection semiconductor device according to the third example of the present disclosure.

Referring to FIG. 9, the ESD protection semiconductor device 300 includes the first to third bidirectional SCR devices 300-1, 300-2, 300-3. The first to third bidirectional SCR devices 300-1, 300-2, 300-3 are collectively surrounded by the single DTI 350, and no DTI is formed between the individual SCR devices.

From the plan view perspective, the first to third bidirectional SCR devices 300-1, 300-2, 300-3 may each include first to third well regions 320, 330, 340, respectively. The N-type deep well region 304 may be formed beneath the first well region 320. The second well region 330 and the third well region 340 are formed on both sides of the first well region 320, and P+ regions 331 and 341, along with N+ regions 332, 342, are formed in the second and third well regions 330, 340, respectively.

In FIG. 9, the ESD protection semiconductor device 300 may include a CAN High terminal region, a CAN low terminal region, and a GND terminal region. The CAN High terminal of the first bidirectional SCR device 300-1 is connected via metal to the CAN High terminal of the second bidirectional SCR device 300-2. Similarly, the CAN Low terminal of the second bidirectional SCR device 300-2 is connected via metal to the CAN Low terminal of the third bidirectional SCR device 300-3. The first to third bidirectional SCR devices 300-1, 300-2, 300-3 are all electrically connected in structure.

As shown in FIG. 9, an N-type guard ring region 390 may be formed in the outermost region in a ring shape, surrounding the first to third bidirectional SCR devices 300-1, 300-2, 300-3. Additionally, as illustrated, an outermost DTI 391 may be further formed outside the N-type guard ring region 390 to provide isolation from other devices.

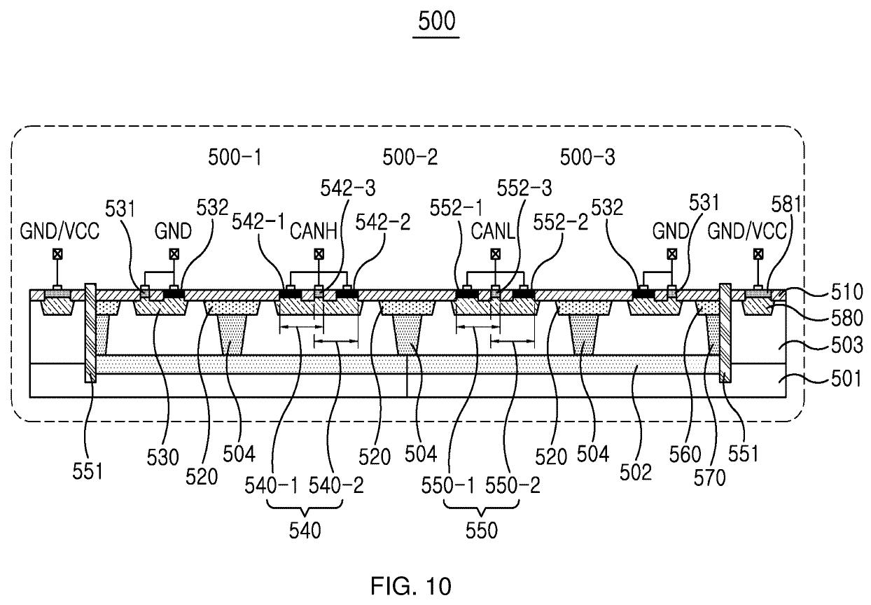

FIG. 10 illustrates a cross-sectional view of an ESD protection semiconductor device according to the fourth example of the present disclosure.

Compared to the ESD protection semiconductor device 300 shown in FIG. 8, an ESD protection semiconductor device 500 of FIG. 10 differs in that portions of a first bidirectional SCR device 500-1 and a second bidirectional SCR device 500-2, and portions of the second bidirectional SCR device 500-2 and a third bidirectional SCR device 500-3, are formed to partially overlap.

In more detail, a third well region 540-1 of the first bidirectional SCR device 500-1 and a second well region 540-2 of the second bidirectional SCR device 500-2 are formed to overlap. Similarly, a third well region 550-1 of the second bidirectional SCR device 500-2 and a second well region 550-2 of the third bidirectional SCR device 500-3 are formed to overlap. In the overlapping regions between the third well region 540-1 of the first bidirectional SCR device 500-1 and the second well region 540-2 of the second bidirectional SCR device 500-2, a P+ region 542-3 is centrally disposed, and N+ regions 542-1, 542-2 are symmetrically formed on the left and right sides of the P+ region 542-3. Likewise, in the overlapping regions between the third well region 550-1 of the second bidirectional SCR device 500-2 and the second well region 550-2 of the third bidirectional SCR device 500-3, a P+ region 552-3 is centrally disposed, and N+ regions 552-1, 552-2 are symmetrically formed on the left and right sides of the P+ region 552-3.

The third well region 540-1 of the first bidirectional SCR device 500-1 and the second well region 540-2 of the second bidirectional SCR device 500-2 are connected to a CAN High terminal. The third well region 550-1 of the second bidirectional SCR device 500-2 and the second well region 550-2 of the third bidirectional SCR device 500-3 are connected to a CAN Low terminal.

The remaining elements are identical to those described with reference to FIG. 8. As shown in FIG. 10, a P-type substrate 501, a P-type epitaxial layer 503, an N-type buried layer 502, a device isolation layer 510, a deep trench isolation (DTI) 551, an N-well 560, a deep N-well (DNW) 570, and a fourth well region 580 are respectively formed.

According to this configuration, the first bidirectional SCR device 500-1 and the second bidirectional SCR device 500-2 may share a single P+ region 542-3, and similarly, the second bidirectional SCR device 500-2 and the third bidirectional SCR device 500-3 may share a single P+ region 552-3. This allows the overall layout to be more compact than that of FIG. 8.

In particular, as shown in FIG. 10, since the number of doped P+ regions in the P-type well region is reduced from two to one compared to other examples, the area of the P-type well region can also be reduced. In general, a reduction in the size of a device leads to a reduction in junction-related capacitance, thereby allowing the pin incorporating the device to operate at higher speed. Furthermore, as the area of the P-type well region is reduced, the pickup resistance of the P-type well region, i.e., the emitter-base resistance (RBE) of a parasitic bipolar junction transistor (BJT), increases. This allows the trigger voltage to be reduced, thereby improving protection of surrounding devices.

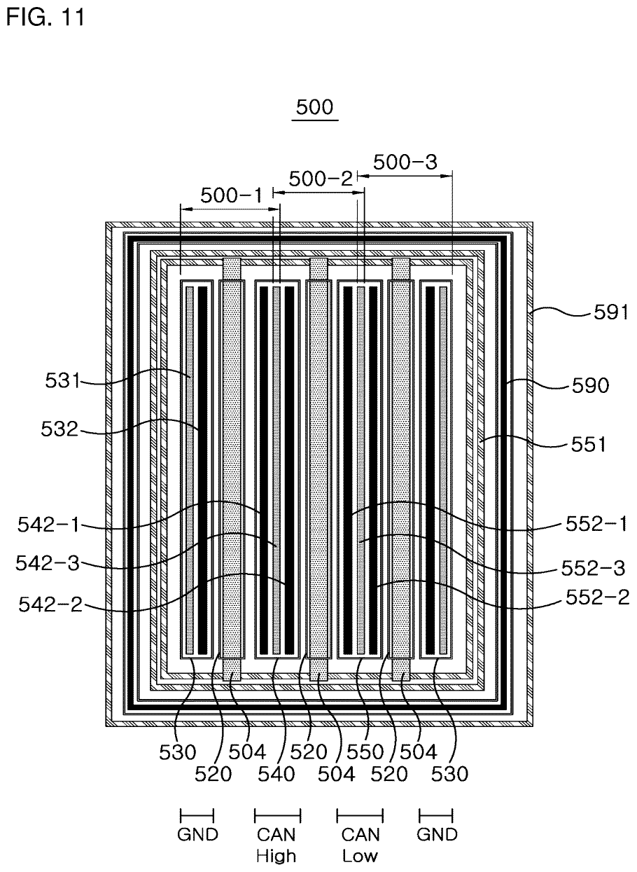

FIG. 11 illustrates a plan view of an ESD protection semiconductor device according to the fourth example of the present disclosure.

Referring to FIG. 11, the ESD protection semiconductor device 500 includes, in a plan view, first to third bidirectional SCR devices 500-1, 500-2, 500-3. The first to third bidirectional SCR devices 500-1, 500-2, 500-3 may be entirely surrounded and defined by one or two deep trench isolations (DTIs) 551. Although two DTIs 551 are illustrated in the plan view of FIG. 11, a single DTI 551 may be used, as shown in the cross-sectional view of FIG. 10. In addition, the first bidirectional SCR device 500-1 and the second bidirectional SCR device 500-2 are partially overlapped with each other, and the second bidirectional SCR device 500-2 and the third bidirectional SCR device 500-3 are also partially overlapped. Through the overlapping regions, the first and second bidirectional SCR devices 500-1 and 500-2 may share a single P+ region 542-3, and the second and third bidirectional SCR devices 500-2 and 500-3 may also share a single P+ region 552-3.

An N-type deep well region (DNW) 504 may be formed below the first well regions 520 of the first to third bidirectional SCR devices 500-1, 500-2, 500-3.

The ESD protection semiconductor device 500 shown in FIG. 11 may include a CAN High terminal region, a CAN Low terminal region, and a GND terminal region.

As further illustrated in FIG. 11, an N-type guard ring region 590 may be formed to surround the first to third bidirectional SCR devices 500-1, 500-2, 500-3 in a ring shape at the outermost perimeter. In addition, as shown in the drawing, an outermost DTI 591 may further be formed outward of the N-type guard ring region 590 to provide isolation from other devices.

The first to fourth examples of the present disclosure include first to third bidirectional SCR devices formed on a single chip, wherein the structural configuration between the respective devices differs among the examples. In the first example, each SCR device is isolated by forming a separate DTI between the devices. In the second example, the devices are isolated by a single DTI formed between them. In the third example, no DTI is formed between the devices. In the fourth example, no DTI is formed between the devices, and portions of the well regions are shared between adjacent devices. Even with such configurations, there is no significant functional difference compared to conventional structures in which a DTI is formed for each bidirectional SCR device and each device is independently constructed. However, the proposed configurations provide advantages in terms of layout efficiency. Specifically, if the layout area of the first example is defined as 100%, the layout area of the second example can be reduced by approximately 8%, the third example by approximately 22%, and the fourth example can be designed with the smallest layout area among all the described examples. Accordingly, all four examples can achieve a smaller layout area compared to the semiconductor device described in FIG. 3.

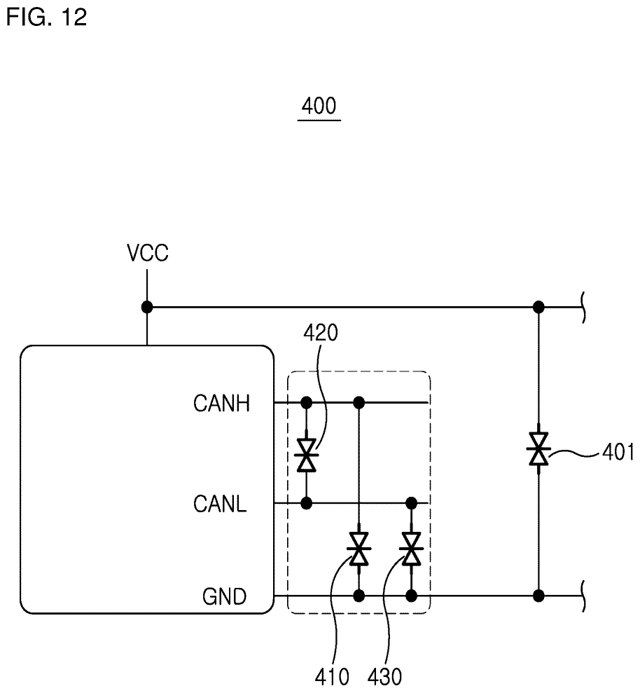

FIG. 12 illustrates a circuit diagram illustrating a CAN transceiver protection circuit applicable to the present disclosure.

A CAN transceiver protection circuit 400 includes four pin terminals: a VCC terminal, a CAN High terminal (CANH), a CAN Low terminal (CANL), and a ground (GND) terminal.

The SCR devices provided in the CAN transceiver protection circuit 400 are bidirectional SCR devices, and a total of four such devices are included.

The SCR devices provided in the CAN transceiver protection circuit 400 are bidirectional SCR devices, and a total of four such devices are provided. In this configuration, a device 401 that connects the VCC terminal and the GND terminal may be implemented as a bidirectional SCR device. Alternatively, the device 401 may be implemented as a bipolar junction transistor (BJT) device or a gate-grounded NMOS (GGNMOS) device.

Among the first to third bidirectional SCR devices described above, the first bidirectional SCR device 410 is connected between the CAN High terminal and the GND terminal, the second bidirectional SCR device 420 is connected between the CAN High terminal and the CAN Low terminal, and the third bidirectional SCR device 430 is connected between the CAN Low terminal and the GND terminal.

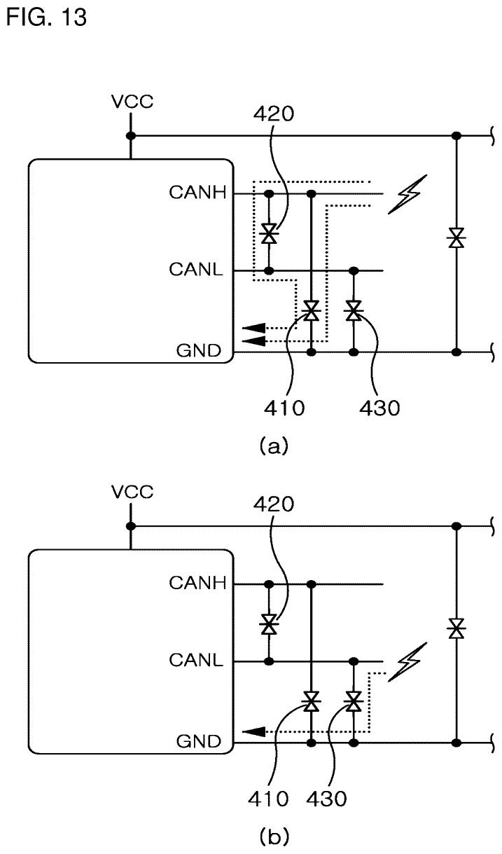

FIG. 13 illustrates an operational state of a CAN transceiver protection circuit according to an example of the present disclosure. With reference to FIG. 13, the operation of the CAN transceiver protection circuit shown in FIG. 11 will be described below.

Referring to (a) of FIG. 13, a case is illustrated in which a surge voltage is applied to the CAN High terminal. In this case, the surge voltage is discharged to the ground terminal either directly through the first bidirectional SCR device 410, or sequentially through the second bidirectional SCR device 420 and the first bidirectional SCR device 410.

Referring to (b) of FIG. 13, a case is illustrated in which a surge voltage is applied to the CAN Low terminal. In this case, the surge voltage is discharged directly to the ground terminal through the third bidirectional SCR device 430.

Accordingly, even if a surge voltage is applied externally to the CAN transceiver protection circuit 400, the surge voltage flows to the ground through the first to third bidirectional SCR devices 410, 420, 430, thereby protecting other circuit components from the surge.

According to examples of the present disclosure, the ESD protection semiconductor device is designed to be integrated on-chip to a level sufficient for system-level ESD evaluation.

Typically, ESD protection semiconductor devices are evaluated based on the Human Body Model (HBM), wherein the surge current is approximately 1.33 A with a rise time of about 10 ns. The HBM evaluation is a test conducted without applying a voltage and is intended to determine the extent to which a semiconductor device may be damaged due to electrostatic discharge.

However, since ESD protection semiconductor devices are used in the course of mass production and are mounted within final products, it is necessary to perform system-level testing. System-level testing involves applying pulse stress to a complete system—including the semiconductor device and the finished product such as a notebook computer, monitor, or vehicle—and monitoring for occurrences such as malfunction, system reset, or power reboot to evaluate the system's response.

Therefore, the semiconductor device of the present disclosure also needs to be evaluated under system-level ESD test conditions. In such evaluations, a higher surge current, approximately 30 A, is used compared to the HBM test. Conventionally, in order to protect the system against such surge currents, additional Transient Voltage Suppression (TVS) diodes have been incorporated into the design. However, such additional configuration may lead to increased manufacturing costs and may cause degradation in signal processing speed.

Accordingly, in the present embodiment, the integrated circuit (IC) is designed to include the ESD protection semiconductor device therein so as to withstand ESD surge currents.

As described above, by integrating the bidirectional SCR devices for ESD protection into a single chip and improving the isolation structure between the bidirectional SCR devices in various forms, it can be confirmed that the semiconductor device may be designed with a reduced layout area compared to the conventional structures.

According to the present disclosure, the boundaries between the first to third bidirectional SCR devices are improved, allowing the spacing between devices to be reduced, thereby minimizing the overall layout area compared to conventional designs.

According to the present disclosure, by implementing the first to third bidirectional SCR devices as on-chip components within an IC, the semiconductor device can withstand system-level ESD tests that are more severe than standard HBM levels, thereby improving the reliability of the semiconductor device.

According to the present disclosure, the IC can be designed with a reduced area of the P-type well region, which increases the pickup resistance of the P-type well. This increase in resistance allows the trigger voltage to be formed at a lower level, thereby enabling more effective protection of the semiconductor device.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
a first bidirectional silicon controlled rectifier (SCR) device, a second bidirectional SCR device, and a third bidirectional SCR device,
wherein each of the first, second, and third bidirectional SCR devices comprises:
a semiconductor substrate of a first conductivity type;
a device isolation layer disposed on the semiconductor substrate;
a first well region of a second conductivity type, a second well region of the first conductivity type, and a third well region of the first conductivity type, each of the first to third well regions being formed separately from one another beneath the device isolation layer; and
two doped regions respectively formed in the second and third well regions, and
wherein the first, second, and third bidirectional SCR devices are integrated on a single chip.

2. The semiconductor device of claim 1,
wherein the two doped regions comprise a doped region of the first conductivity type and a doped region of the second conductivity type, and
wherein the doped region of the first conductivity type is smaller in size than the doped region of the second conductivity type.

3. The semiconductor device of claim 1,
wherein a doped region of the first bidirectional SCR device is electrically connected to a ground (GND) terminal and a CAN high terminal,
wherein a doped region of the second bidirectional SCR device is electrically connected to the CAN high terminal and a CAN low terminal,
wherein a doped region of the third bidirectional SCR device is electrically connected to the CAN low terminal and the ground (GND) terminal,
wherein the CAN high terminal of the first bidirectional SCR device is electrically connected to the CAN high terminal of the second bidirectional SCR device, and
wherein the CAN low terminal of the second bidirectional SCR device is electrically connected to the CAN low terminal of the third bidirectional SCR device.

4. The semiconductor device of claim 1, wherein no doped region is formed in the first well region.

5. The semiconductor device of claim 1,
wherein one or two deep trench isolation (DTI) structures are formed between the first and second bidirectional SCR devices and between the second and third bidirectional SCR devices.

6. The semiconductor device of claim 1,
wherein no deep trench isolation (DTI) structure is formed between the first and second bidirectional SCR devices and between the second and third bidirectional SCR devices.

7. The semiconductor device of claim 1,
wherein the semiconductor substrate of the first conductivity type comprises:
a buried layer of the second conductivity type;
an epitaxial layer of the first conductivity type formed over the buried layer; and
a deep well region of the second conductivity type formed beneath the first well region, and
wherein the deep well region electrically connects the first well region to the buried layer.

8. A semiconductor device comprising:
a first bidirectional silicon controlled rectifier (SCR) device, a second bidirectional SCR device, and a third bidirectional SCR device, each disposed on a single chip,
wherein each of the first, second, and third bidirectional SCR devices comprises:
a first well region of a second conductivity type formed at a central portion;
a second well region and a third well region of a first conductivity type symmetrically formed on opposite sides of the first well region;
a deep well region of the second conductivity type formed beneath the first well region; and
a doped region of the first conductivity type and a doped region of the second conductivity type formed in the second well region and the third well region.

9. The semiconductor device of claim 8,
wherein the first bidirectional SCR device is electrically connected between a ground (GND) terminal and a CAN high terminal;
wherein the second bidirectional SCR device is electrically connected between the CAN high terminal and a CAN low terminal;
wherein the third bidirectional SCR device is electrically connected between the CAN low terminal and the ground terminal;
wherein the CAN high terminal of the first bidirectional SCR device is metal-connected to the CAN high terminal of the second bidirectional SCR device; and
wherein the CAN low terminal of the second bidirectional SCR device is metal-connected to the CAN low terminal of the third bidirectional SCR device.

10. The semiconductor device of claim 8, further comprising:
a guard ring region of the second conductivity type formed to surround the first, second, and third bidirectional SCR devices; and
a deep trench isolation (DTI) structure formed outside the guard ring region.

11. A controller area network (CAN) protection circuit comprising:
a first bidirectional SCR device, a second bidirectional SCR device, and a third bidirectional SCR device; and
a CAN receiver having a VCC terminal, a CAN high terminal, a CAN low terminal, and a ground (GND) terminal,
wherein the first bidirectional SCR device is connected between the CAN high terminal and the GND terminal;
wherein the second bidirectional SCR device is connected between the CAN high terminal and the CAN low terminal; and
wherein the third bidirectional SCR device is connected between the CAN low terminal and the GND terminal.

12. The CAN protection circuit of claim 11,
wherein the first, second, and third bidirectional SCR devices are implemented on a single chip.

13. The CAN protection circuit of claim 11, further comprising:
a semiconductor protection device connected between the VCC terminal and the GND terminal,
wherein the semiconductor protection device comprises one of:
a bidirectional SCR device, a bipolar junction transistor (BJT), or a gate-grounded NMOS (GGNMOS) device.

14. The CAN protection circuit of claim 11,
wherein each of the first, second, and third bidirectional SCR devices comprises:
a semiconductor substrate of a first conductivity type;
a device isolation layer formed on the semiconductor substrate;
a first well region of a second conductivity type, a second well region of the first conductivity type, and a third well region of the first conductivity type, each formed separately beneath the device isolation layer; and
doped regions of the first conductivity type and the second conductivity type respectively formed in the second well region and the third well region, and
wherein no doped region is formed in the first well region.

15. A semiconductor device comprising:
a first bidirectional silicon controlled rectifier (SCR) device, a second bidirectional SCR device, and a third bidirectional SCR device, each disposed on a single chip;
a first well region of a second conductivity type formed at a central portion of the chip;
a second well region and a third well region of a first conductivity type symmetrically formed on respective left and right sides of the first well region;
a doped region of the first conductivity type formed in each of the second and third well regions; and
doped regions of the second conductivity type formed on opposite sides of the doped region of the first conductivity type in each of the second and third well regions,
wherein a controller area network (CAN) high terminal is connected to the doped region of the first conductivity type and the doped regions of the second conductivity type in the second well region, and
wherein a CAN low terminal is connected to the doped region of the first conductivity type and the doped regions of the second conductivity type formed in the third well region.

16. The semiconductor device of claim 15,
wherein a deep trench isolation (DTI) structure is formed to surround the first, second, and third bidirectional SCR devices, and
wherein a guard ring of the second conductivity type is formed outside the DTI structure.

17. The semiconductor device of claim 15,
wherein the first bidirectional SCR device is connected between a ground (GND) terminal and the CAN high terminal,
wherein the second bidirectional SCR device is connected between the CAN high terminal and the CAN low terminal, and
wherein the third bidirectional SCR device is connected between the CAN low terminal and the GND terminal.

18. The semiconductor device of claim 17,
wherein the GND terminal of the first bidirectional SCR device includes a fourth well region of the first conductivity type, the fourth well region comprising doped regions of both the first and second conductivity types, and
wherein the ground terminal of the third bidirectional SCR device includes a fifth well region of the first conductivity type, the fifth well region comprising doped regions of both the first and second conductivity types.
